(19) United States
(12) Patent Application Publication
(10) Pub. No.: US 2025/0063699 A1
(43) Pub. Date: Feb. 20, 2025

(54) REFRIGERATION SYSTEM FOR DATA CENTER, AND DATA CENTER

(71) Applicant: Hebei Qinhuai Data Co., Limited., Zhangjiakou City (CN)

(72) Inventor: Binghua ZHANG, Zhangjiakou City, Hebei Province (CN)

(21) Appl. No.: 18/804,989

(22) Filed: Aug. 14, 2024

(30) Foreign Application Priority Data
Aug. 16, 2023 (CN) 202311030411.0

(51) Int. Cl. H05K 7/20

(52) U.S. Cl. CPC H05K 7/208; H05K 7/20718

(57) ABSTRACT

The present disclosure relates to the field of refrigeration system technology, and discloses a refrigeration system for a data center. The data center includes a liquid-cooled server, and the refrigeration system includes a liquid cooling system and an air cooling system. The liquid cooling system includes a compressor, a first cooler, and a plate heat exchanger constituting a refrigerant circulation circuit. The plate heat exchanger includes a first branch and a second branch, where the first branch is configured to circulate a refrigerant, the second branch is configured to circulate a coolant, and the second branch is communicated with a liquid cooling plate of the liquid-cooled server. The air cooling system includes a second cooler, a refrigerant drive apparatus, a throttling apparatus, and an evaporator constituting another refrigerant circulation circuit. An inlet of the second cooler is communicated with an outlet of the first branch of the plate heat exchanger.

### CROSS REFERENCE TO RELATED APPLICATION

This application claims priority to Chinese Patent Application No. 202311030411.0, titled “REFRIGERATION SYSTEM FOR DATA CENTER, AND DATA CENTER” and filed to the China National Intellectual Property Administration on Aug. 16, 2023, the entire contents of which are incorporated herein by reference.

### TECHNICAL FIELD

The present disclosure relates to the field of refrigeration system technology, and more particularly, to a refrigeration system for a data center, and the data center.

### BACKGROUND

Currently, with the improvement of server performance, demands for heat dissipation of server chips and other components are also increasing accordingly.

In related technologies, cold plate liquid-cooled servers are generally used in data centers to solve the problem of heat dissipation. However, by means of liquid cooling systems, the cold plate liquid-cooled servers can only dissipate heat from components with higher heat generation such as chips. Other components with lower heat generation in the servers rely on the servers' own cooling fans to dissipate heat, which results in lower heat dissipation efficiency.

It is to be noted that the above information disclosed in this Background section is only for enhancement of understanding of the background of the present disclosure and therefore it may contain information that does not form the prior art that is already known to a person of ordinary skill in the art.

### SUMMARY

To have a basic understanding of some aspects of the disclosed embodiments, a brief summary is provided below. The summary neither is a general review, nor is intended to determine key/important constituent elements or describe a protection scope of these embodiments, but rather serves as a preface to the detailed description that follows.

The embodiments of the present disclosure provide a refrigeration system for a data center and the data center, which can improve heat dissipation efficiency of a server in the data center.

In some embodiments, the data center includes a liquid-cooled server, and the refrigeration system includes a liquid cooling system and an air cooling system.

The liquid cooling system includes a compressor, a first cooler, and a plate heat exchanger constituting a refrigerant circulation circuit. The plate heat exchanger includes a first branch and a second branch, where the first branch is configured to circulate a refrigerant, the second branch is configured to circulate a coolant, and the second branch is communicated with a liquid cooling plate of the liquid-cooled server. The first branch and the second branch may exchange heat, and the coolant flowing out of the second branch flows through the liquid cooling plate to dissipate heat from the liquid-cooled server.

The air cooling system includes a second cooler, a refrigerant drive apparatus, a throttling apparatus, and an evaporator constituting another refrigerant circulation circuit. An inlet of the second cooler is communicated with an outlet of the first branch of the plate heat exchanger; and the refrigerant flows into the evaporator after being throttled by the throttling apparatus to dissipate the heat from the liquid-cooled server.

In some embodiments, the data center includes at least one liquid-cooled server and the aforementioned refrigeration system for cooling the liquid-cooled server.

The refrigeration system for the data center and the data center provided in the embodiments of the present disclosure can achieve following technical effects.

During the operation of the data center, first, the compressor in the liquid cooling system can compress a low-temperature and low-pressure gaseous refrigerant into a high-temperature and high-pressure gaseous refrigerant, which flows into the first cooler and is cooled into a high-temperature and high-pressure liquid refrigerant. The high-temperature and high-pressure liquid refrigerant flows into the first branch of the plate heat exchanger to exchange heat with the coolant in the second branch, such that the refrigerant absorbs heat when flowing through the first branch and thus is converted into the high-temperature and high-pressure gaseous refrigerant. After the coolant in the second branch releases heat, it flows through the liquid cooling plate to dissipate heat from the liquid-cooled server. That is, the coolant dissipates heat from a component with higher heat generation such as a chip in the liquid-cooled server. Second, the high-temperature and high-pressure gaseous refrigerant flowing out of the first branch of the plate heat exchanger flows into the second cooler and is cooled into the high-temperature and high-pressure liquid refrigerant. The high-temperature and high-pressure liquid refrigerant flows into the throttling apparatus under the action of the refrigerant drive apparatus, and is converted into a low-temperature and low-pressure liquid refrigerant after being throttled by the throttling apparatus. Next, the low-temperature and low-pressure liquid refrigerant flows into the evaporator to absorb heat and then is converted into the low-temperature and low-pressure gaseous refrigerant to achieve heat dissipation of the liquid-cooled server by means of air cooling.

In this way, compared with a mode where the liquid-cooled server relies on liquid cooling and its own fan cooling, the refrigeration mode of the liquid-cooled server in the embodiments of the present disclosure has better heat dissipation effects. Thus, heat dissipation efficiency of the server in the data center can be improved.

Both the foregoing general description and the following detailed description are exemplary and explanatory only and are not intended to limit the present disclosure.

### BRIEF DESCRIPTION OF THE DRAWINGS

Exemplary descriptions are made to one or more embodiments with reference to pictures in the corresponding drawings, and these exemplary descriptions and drawings do not constitute limitations on the embodiments, and elements with the same reference numerals in the drawings are denoted as similar elements. Unless otherwise stated, the drawings do not constitute a scale limitation, in which:

FIG. 1 is a schematic diagram of a data center according to an embodiment of the present disclosure;

FIG. 2 is a schematic diagram of connection between a plurality of evaporators according to an embodiment of the present disclosure; and

FIG. 3 is a schematic diagram of electrical connection of a data center according to an embodiment of the present disclosure.

### REFERENCE NUMERALS IN THE ATTACHED DRAWINGS

data center 100; liquid cooling system 1; air cooling system 2; compressor 11; first cooler 12; plate heat exchanger 13; coolant circulation pump 14; first cooling pipe 121; first fan 122; first reservoir 123; first jet apparatus 124; first circulating water pump 125; first water inlet pipe 126; first water outlet pipe 127; first branch 131; second branch 312; second cooler 21; refrigerant drive apparatus 22; throttling apparatus 23; evaporator 24; second cooling pipe 211; second fan 212; second reservoir 213; second jet apparatus 214; second circulating water pump 215; second water inlet pipe 216; and second water outlet pipe 217.

### DETAILED DESCRIPTION

To gain a more detailed understanding of the characteristics and technical contents of the embodiments of the present disclosure, a detailed description is made to implementation of the embodiments of the present disclosure in conjunction with the accompanying drawings, which serve for reference only and are not intended to limit the embodiments of the present disclosure. In the following technical description, for convenience of explanation, multiple details are provided to provide a comprehensive understanding of the disclosed embodiments. However, one or more embodiments can still be implemented without these details. In other cases, to simplify the drawings, familiar structures and apparatuses can be simplified for display.

In the specification, the claims and the foregoing accompanying drawings of the embodiments of the present disclosure, a term such as “first” or “second” is intended to separate between similar objects but is not intended to describe a specific sequence or precedence order. It is to be understood that data used like this may be interchangeable where appropriate, such that the embodiments of the present disclosure described herein may be implemented. Furthermore, the terms “comprise” and “have” as well as variants thereof are intended to cover non-exclusive inclusion.

Unless otherwise stated, the term “a plurality of” refers to two or more.

In the embodiments of the present disclosure, the character “/” indicates that an “or” relationship is between association objects. For example, A/B represents A or B.

The term “and/or” used for describing an association relationship between the association objects represents presence of three relationships. For example, A and/or B may represent presence of the A only, presence of both the A and the B, and presence of the B only.

The term “correspondence” may refer to an association relationship or a binding relationship, and that A corresponds to B refers to an association relationship or a binding relationship between A and B.

Currently, with the improvement of server performance, demands for heat dissipation of server chips and other components are also increasing accordingly. In related technologies, cold plate liquid-cooled servers are generally used in data centers to solve the problem of heat dissipation. However, by means of liquid cooling systems, the cold plate liquid-cooled servers can only dissipate heat from components with higher heat generation such as chips. Other components with lower heat generation in the servers rely on the servers' own cooling fans to dissipate heat, which results in lower heat dissipation efficiency.

In view of this, the embodiments of the present disclosure provide a refrigeration system for a data center, and the data center. In the process of cooling the data center by the refrigeration system, compared with a mode where the liquid-cooled server relies on liquid cooling and its own fan cooling, the refrigeration mode of this refrigeration system has better heat dissipation effects. Thus, heat dissipation efficiency of the server in the data center can be improved.

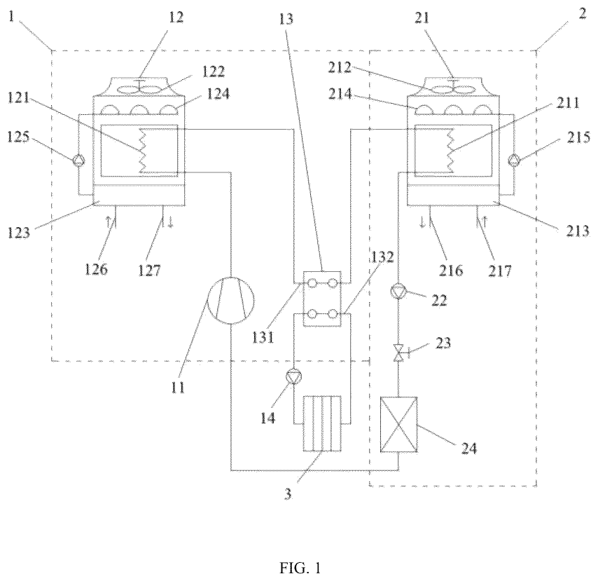

With reference to FIG. 1, the embodiments of the present disclosure provide a data center 100, including a refrigeration system and at least one liquid-cooled server 3. The refrigeration system includes a liquid cooling system 1 and an air cooling system 2. The liquid cooling system 1 and the air cooling system 2 are configured to dissipate heat from the liquid-cooled server 3, respectively.

The liquid cooling system 1 includes a compressor 11, a first cooler 12, and a plate heat exchanger 13 that constitute a refrigerant circulation circuit. The plate heat exchanger 13 includes a first branch 131 and a second branch 132, where the first branch 131 is configured to circulate a refrigerant. The second branch 132 is configured to circulate a coolant, and the second branch 132 is communicated with a liquid cooling plate of the liquid-cooled server 131. The first branch 131 and the second branch 132 can exchange heat, and the coolant flowing out of the second branch 132 flows through the liquid cooling plate to dissipate heat from the liquid-cooled server 3.

The air cooling system 2 includes a second cooler 21, a refrigerant drive apparatus 22, a throttling apparatus 23, and at least one evaporator 24 that constitute another refrigerant circulation circuit. An inlet of the second cooler 21 is communicated with an outlet of the first branch 131 of the plate heat exchanger 13. In the air cooling system 2, the refrigerant flows into the evaporator 24 after being throttled by the throttling apparatus 23 to dissipate the heat from the liquid-cooled server 3.

In the embodiments of the present disclosure, during the operation of the data center 100, first, the compressor 11 in the liquid cooling system 1 can compress a low-temperature and low-pressure gaseous refrigerant into a high-temperature and high-pressure gaseous refrigerant, which flows into the first cooler 12 and is cooled into a high-temperature and high-pressure liquid refrigerant. The high-temperature and high-pressure liquid refrigerant flows into the first branch 131 of the plate heat exchanger 13 to exchange heat with the coolant in the second branch 132, such that the refrigerant absorbs heat when flowing through the first branch 131 and thus is converted into the high-temperature and high-pressure gaseous refrigerant. After the coolant in the second branch 132 releases heat, it flows through the liquid cooling plate to dissipate heat from the liquid-cooled server 3. That is, the coolant dissipates heat from a component with higher heat generation such as a chip in the liquid-cooled server 3. Second, the high-temperature and high-pressure gaseous refrigerant flowing out of the first branch 131 of the plate heat exchanger 13 flows into the second cooler 21 and is cooled into the high-temperature and high-pressure liquid refrigerant. The high-temperature and high-pressure liquid refrigerant flows into the throttling apparatus 23 under the action of the refrigerant drive apparatus 22, and is converted into a low-temperature and low-pressure liquid refrigerant after being throttled by the throttling apparatus 23. Next, the low-temperature and low-pressure liquid refrigerant flows into the evaporator 24 to absorb heat and then is converted into the low-temperature and low-pressure gaseous refrigerant to achieve heat dissipation of the liquid-cooled server 3 by means of air cooling. In this way, compared with the mode where the liquid-cooled server relies on liquid cooling and its own fan cooling, the refrigeration mode of the liquid-cooled server in the embodiments of the present disclosure has better heat dissipation effects. Thus, the heat dissipation efficiency of the server in the data center can be improved.

In addition, in the data center 100 of the embodiments of the present disclosure, on a liquid cooling side and an air cooling side, the first cooler 12 and the second cooler 21 are employed to carry out double cooling, respectively, to achieve cascade refrigeration of the refrigeration system. In this way, it is avoidable a case where the compressor 11 is damaged due to overheating caused by excessive temperature of the refrigerant in the refrigeration pipeline.

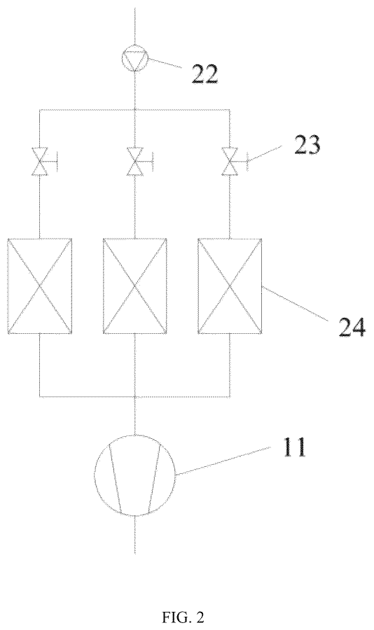

Alternatively, with reference to FIG. 2, when there are a plurality of evaporators 24 in the embodiments of the present disclosure, a throttling apparatus 23 may be correspondingly arranged at the inlet of each evaporator 24, and the plurality of evaporators 24 are connected in parallel. In this way, the same air cooling system 2 may separately dissipate heat for different liquid-cooled servers 3 by means of the plurality of evaporators 24, thereby improving the heat dissipation efficiency.

Alternatively, the second branch 132 of the plate heat exchanger 13 is provided with a coolant circulation pump 14, which is configured to transport the coolant circulating in the second branch 132 to the liquid cooling plate of the liquid-cooled server 3. Thus, heat is dissipated from the liquid-cooled server 3 by means of the coolant.

Alternatively, the first cooler 12 in the embodiments of the present disclosure may be an evaporative cooler. The first cooler 12 includes a first cooling pipe 121, a first fan 122, a first reservoir 123, a first jet apparatus 124, and a first circulating water pump 125. The first cooling pipe 121 is arranged inside the first cooler 12 and is communicated with a refrigerant pipeline of the liquid cooling system 1, and the first cooling pipe 121 is configured to cool the refrigerant in the refrigerant pipeline. The first fan 122 is configured to dissipate the heat from the first cooling pipe 121. The first reservoir 123 is arranged on a bottom of the first cooler 12, and is configured to store cooling water. The first jet apparatus 124 is arranged inside the first cooler 12, and is configured to jet the cooling water into the first cooling pipe 121. The first circulating water pump 125 is connected to the first reservoir 123 and the first jet apparatus 124, respectively, to extract the cooling water from the first reservoir 123 and convey the cooling water to the first jet apparatus 124.

In this embodiment, during the process of cooling the high-temperature and high-pressure gaseous refrigerant discharged from the compressor 11 by means of the first cooler 12, the first circulating water pump 125 extracts the cooling water from the first reservoir 123 and conveys the cooling water to the first jet apparatus 124. The cooling water is jetted onto the first cooling pipe 121 by means of the first jet apparatus 124, such that the cooling water evaporates and absorbs heat on an outer surface of the first cooling pipe 121, thereby cooling the refrigerant inside the first cooling pipe 121. In addition, the first fan 122 extracts air and blows it around the first cooling pipe 121, which can further improve an evaporation rate of the cooling water on the outer surface of the first cooling pipe 121, such that it is beneficial for the first cooler 12 to better cool the refrigerant.

Alternatively, the first reservoir 123 includes a first water inlet pipe 126 and a first water outlet pipe 127, both of which are arranged on the bottom of the first reservoir 123. In this way, when the first reservoir 123 needs to be replenished with the cooling water, the cooling water may be cyclically replenished through the first water inlet pipe 126 and the first water outlet pipe 127.

Alternatively, the second cooler 21 in the embodiments of the present disclosure may be an evaporative cooler. The second cooler 21 includes a second cooling pipe 211, a second fan 212, a second reservoir 213, a second jet apparatus 214, and a second circulating water pump 215. The second cooling pipe 211 is arranged inside the second cooler 21 and is communicated with a refrigerant pipeline of the air cooling system 2, and the second cooling pipe 211 is configured to cool the refrigerant in the refrigerant pipeline. The second fan 212 is configured to dissipate heat from the second cooling pipe 211. The second reservoir 213 is arranged on a bottom of the second cooler 21, and is configured to store cooling water. The second jet apparatus 214 is arranged inside the second cooler 21, and is configured to jet the cooling water into the second cooling pipe 211. The second circulating water pump 215 is separately connected to the second reservoir 213 and the second jet apparatus 214, and is configured to extract the cooling water from the second reservoir 213 and convey the cooling water to the second jet apparatus 214.

In this embodiment, during the process of cooling the high-temperature and high-pressure gaseous refrigerant flowing out of the first branch of the plate heat exchanger 13 by means of the second cooler 21, the second circulating water pump 215 extracts the cooling water from the second reservoir 213 and conveys the cooling water to the second jet apparatus 214. The cooling water is jetted onto the second cooling pipe 211 by means of the second jet apparatus 214, such that the cooling water evaporates and absorbs heat on an outer surface of the second cooling pipe 211, thereby cooling the refrigerant inside the second cooling pipe 211. In addition, the second fan 212 extracts air and blows it around the second cooling pipe 211, which can further improve the evaporation rate of the cooling water on the outer surface of the second cooling pipe 211, such that it is beneficial for the second cooler 21 to better cool the refrigerant.

Alternatively, the second reservoir 213 includes a second water inlet pipe 216 and a second water outlet pipe 217, both of which are arranged on the bottom of the second reservoir 213. In this way, when the second reservoir 213 needs to be replenished with the cooling water, the cooling water may be cyclically replenished through the second water inlet pipe 216 and the second water outlet pipe 217.

Alternatively, in the embodiments of the present disclosure, the compressor 11 may be a magnetic levitation centrifugal compressor. Because the magnetic levitation centrifugal compressor can operate at a low-pressure ratio, it is advantageous to save energy.

Alternatively, in the embodiments of the present disclosure, the refrigerant drive apparatus may be a fluorine pump. In this way, in the air cooling system 2, the refrigerant in the refrigeration pipeline is transported by means of the fluorine pump, which can better save the energy compared to transporting the refrigerant in the refrigeration pipeline by means of the compressor.

Alternatively, in the embodiments of the present disclosure, the throttling apparatus 23 may be an electronic expansion valve, a thermal expansion valve, or a capillary tube, but is not limited thereto.

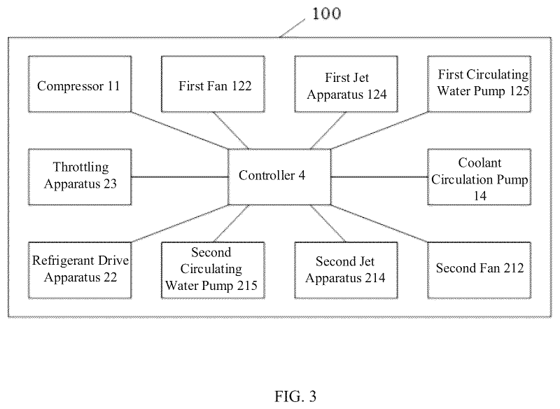

Alternatively, with reference to FIG. 3, the data center 100 provided in the embodiments of the present disclosure may also include a controller 4. The controller 4 is electrically connected to the compressor 11, the first fan 122, the first jet apparatus 124, the first circulating water pump 125, the coolant circulation pump 14, the second fan 212, the second jet apparatus 214, the second circulating water pump 215, the refrigerant drive apparatus 22, and the throttling apparatus 23, respectively, to achieve a control operation.

The technical solutions of the embodiments of the present disclosure may be embodied in the form of software products, which may be stored in a storage medium, including one or more instructions to cause a computer device (a personal computer, a server or a network device and so on) to execute all or part of steps of the method as recited in the embodiments of the present disclosure. The foregoing storage medium may be various medium that can store program codes, such as a Universal Serial Bus (USB) flash disk, a removable hard disk, a read-only memory (ROM), a random-access memory (RAM), a magnetic disk, or an optical disc. The storage medium may also be transient storage medium.

The above descriptions and the accompanying drawings fully illustrate the embodiments of the present disclosure to enable those skilled in the art to practice them. Other embodiments may include structural, logical, electrical, process, and other changes. The embodiments only represent possible changes. Unless explicitly specified, independent components and functions are optional, and an operation sequence may change. Portions and features of some embodiments can be included in, or substituted for, those of other embodiments. Moreover, the terms used in the present disclosure are only for describing the embodiments and are not intended to limit the claims. As used in the descriptions of the embodiments and the claims, singular forms “a”, “an”, and “the” are intended to also include plural forms, unless the context clearly indicates otherwise. Similarly, as used in the present disclosure, the term “and/or” refers to any and all possible combinations that include one or more associated lists. In addition, the term “comprise” and its variants such as “comprises” and/or “comprising” used in the present disclosure refer to the presence of the stated features, integers, steps, operations, elements, and/or components, but not exclusive of the presence or addition of one or more other features, integers, steps, operations, elements, components, and/or groups of thereof. In the case of no more restrictions, elements restricted by a sentence “include a . . . ” do not exclude the fact that additional identical elements may exist in a process, a method or a device of these elements. Herein, each of the embodiments is focused on difference from other embodiments, and references may be made among these embodiments with respect to the same or similar portions among these embodiments. For the methods, products, etc. disclosed in the embodiments, if they correspond to the method section disclosed in the embodiments, reference may be made to the description of the method section for relevant parts.

Those skilled in the art may realize that units and algorithm steps in various examples as described in embodiments disclosed herein can be implemented by electronic hardware or a combination of computer software and electronic hardware. Whether these functions are executed in a hardware mode or a software mode depends on specific applications and design constraints on the technical solutions. Those skilled in the art may use different methods to implement the functions set forth in each of the specific applications. However, the implementation shall be not believed beyond the scope of the embodiments of the present disclosure. Those skilled in the art may clearly understand that for a convenient and concise description, a concrete work process of systems, apparatuses and units described above may refer to a corresponding process of the foregoing method embodiments, which is not repeated anymore herein.

In the embodiments disclosed herein, the disclosed methods and products (including but not limited to apparatuses, devices, etc.) may be implemented through other means. For example, the apparatus embodiments described above are merely exemplary. For example, a unit partition is merely a logic functional partition. In actual implementation, additional manners of partitioning may be available. For example, a plurality of units or components may be combined or integrated into another system, or some features may be ignored or not executed. In addition, intercoupling or direct coupling or communications connection displayed or discussed may be indirect coupling or communications connection, electrical or mechanical or in other forms, by means of some interfaces, apparatuses or units. The unit serving as a detached component may be or not be physically detached, the component serving as a unit display may be or not be a physical unit, i.e., either located at one place or distributed on a plurality of network elements. Units may be selected in part or in whole according to actual needs to achieve this embodiment. In addition, various functional units in the embodiments of the present disclosure may be integrated into one processing unit, or various units may be separately or physically existent, or two or more units may be integrated into one unit.

The flowcharts and block diagrams in the drawings illustrate architectures, functions and operations that may be implemented according to the system, the method and the computer program product of the embodiments of the present disclosure. In this regard, each block in the flowcharts and block diagrams may represent a module, a program segment, or a code portion. The module, the program segment, or the code portion includes one or more executable instructions for implementing the specified logical function. In some alternative implementations, the functions denoted by the blocks may occur in a sequence different from the sequences shown in the drawings. For example, in practice, two blocks in succession may be executed, depending on the involved functionalities, substantially in parallel, or in a reverse sequence. In the description corresponding to the flowcharts and block diagrams in the attached drawings, the operations or steps corresponding to different blocks may also occur in a different order than disclosed in the description, and sometimes there is no specific order between different operations or steps. For example, in practice, two operations or steps in succession may be executed, depending on the involved functionalities, substantially in parallel, or in a reverse sequence. Each block in the block diagrams and/or the flowcharts and/or a combination of the blocks in the block diagrams and/or the flowcharts may be implemented by a dedicated hardware-based system executing specific functions or operations, or by a combination of a dedicated hardware and computer instructions.

What is claimed is:

1. A refrigeration system for a data center, wherein the data center comprises a liquid-cooled server, and the refrigeration system comprises a liquid cooling system and an air cooling system;
the liquid cooling system comprises a compressor, a first cooler, and a plate heat exchanger constituting a refrigerant circulation circuit; the plate heat exchanger comprises a first branch and a second branch, the first branch is configured to circulate a refrigerant, the second branch is configured to circulate a coolant, and the second branch is communicated with a liquid cooling plate of the liquid-cooled server; the first branch and the second branch exchange heat, and the coolant flowing out of the second branch flows through the liquid cooling plate to dissipate heat from the liquid-cooled server; and
the air cooling system comprises a second cooler, a refrigerant drive apparatus, a throttling apparatus, and an evaporator constituting another refrigerant circulation circuit; an inlet of the second cooler is communicated with an outlet of the first branch of the plate heat exchanger; and the refrigerant flows into the evaporator after being throttled by the throttling apparatus to dissipate the heat from the liquid-cooled server.

2. The refrigeration system according to claim 1, wherein the second branch is provided with a coolant circulation pump configured to transport the coolant circulating in the second branch to the liquid cooling plate of the liquid-cooled server.

3. The refrigeration system according to claim 1, wherein the first cooler is an evaporative cooler; and the first cooler comprises:
a first cooling pipe arranged inside the first cooler and communicated with a refrigerant pipeline of the liquid cooling system, the first cooling pipe being configured to cool the refrigerant in the refrigerant pipeline;
a first fan configured to dissipate heat from the first cooling pipe;
a first reservoir arranged on a bottom of the first cooler, the first reservoir being configured to store cooling water;
a first jet apparatus arranged inside the first cooler, the first jet apparatus being configured to jet the cooling water into the first cooling pipe; and
a first circulating water pump connected to the first reservoir and the first jet apparatus, respectively, the first circulating water pump being configured to extract the cooling water from the first reservoir and convey the cooling water to the first jet apparatus.

4. The refrigeration system according to claim 3, wherein the first reservoir comprises:
a first water inlet pipe and a first water outlet pipe arranged on a bottom of the first reservoir.

5. The refrigeration system according to claim 1, wherein the second cooler is an evaporative cooler; and the second cooler comprises:
a second cooling pipe arranged inside the second cooler and communicated with a refrigerant pipeline of the air cooling system, the second cooling pipe being configured to cool the refrigerant in the refrigerant pipeline;
a second fan configured to dissipate heat from the first cooling pipe;
a second reservoir arranged on a bottom of the second cooler, the second reservoir being configured to store cooling water;
a second jet apparatus arranged inside the second cooler, the second jet apparatus being configured to jet the cooling water into the second cooling pipe; and
a second circulating water pump connected to the second reservoir and the second jet apparatus, respectively, the second circulating water pump being configured to extract the cooling water from the second reservoir and convey the cooling water to the second jet apparatus.

6. The refrigeration system according to claim 5, wherein the second reservoir comprises:
a second water inlet pipe and a second water outlet pipe arranged on a bottom of the second reservoir.

7. The refrigeration system according to claim 1, wherein the compressor is a magnetic levitation centrifugal compressor.

8. The refrigeration system according to claim 1, wherein the refrigerant drive apparatus is a fluorine pump.

9. The refrigeration system according to claim 1, wherein the throttling apparatus is an electronic expansion valve, a thermal expansion valve, or a capillary tube.

10. A data center comprising at least one liquid-cooled server and a refrigeration system; the refrigeration system comprising a liquid cooling system and an air cooling system;
the liquid cooling system comprises a compressor, a first cooler, and a plate heat exchanger constituting a refrigerant circulation circuit; the plate heat exchanger comprises a first branch and a second branch, the first branch is configured to circulate a refrigerant, the second branch is configured to circulate a coolant, and the second branch is communicated with a liquid cooling plate of the liquid-cooled server; the first branch and the second branch exchange heat, and the coolant flowing out of the second branch flows through the liquid cooling plate to dissipate heat from the liquid-cooled server; and
the air cooling system comprises a second cooler, a refrigerant drive apparatus, a throttling apparatus, and an evaporator constituting another refrigerant circulation circuit; an inlet of the second cooler is communicated with an outlet of the first branch of the plate heat exchanger; and the refrigerant flows into the evaporator after being throttled by the throttling apparatus to dissipate the heat from the liquid-cooled server.

11. The data center according to claim 10, wherein the second branch is provided with a coolant circulation pump configured to transport the coolant circulating in the second branch to the liquid cooling plate of the liquid-cooled server.

12. The data center according to claim 10, wherein the first cooler is an evaporative cooler; and the first cooler comprises:
a first cooling pipe arranged inside the first cooler and communicated with a refrigerant pipeline of the liquid cooling system, the first cooling pipe being configured to cool the refrigerant in the refrigerant pipeline;
a first fan configured to dissipate heat from the first cooling pipe;
a first reservoir arranged on a bottom of the first cooler, the first reservoir being configured to store cooling water;
a first jet apparatus arranged inside the first cooler, the first jet apparatus being configured to jet the cooling water into the first cooling pipe; and
a first circulating water pump connected to the first reservoir and the first jet apparatus, respectively, the first circulating water pump being configured to extract the cooling water from the first reservoir and convey the cooling water to the first jet apparatus.

13. The data center according to claim 12, wherein the first reservoir comprises:
a first water inlet pipe and a first water outlet pipe arranged on a bottom of the first reservoir.

14. The data center according to claim 10, wherein the second cooler is an evaporative cooler; and the second cooler comprises:
a second cooling pipe arranged inside the second cooler and communicated with a refrigerant pipeline of the air cooling system, the second cooling pipe being configured to cool the refrigerant in the refrigerant pipeline;
a second fan configured to dissipate heat from the first cooling pipe;
a second reservoir arranged on a bottom of the second cooler, the second reservoir being configured to store cooling water;
a second jet apparatus arranged inside the second cooler, the second jet apparatus being configured to jet the cooling water into the second cooling pipe; and
a second circulating water pump connected to the second reservoir and the second jet apparatus, respectively, the second circulating water pump being configured to extract the cooling water from the second reservoir and convey the cooling water to the second jet apparatus.

15. The data center according to claim 14, wherein the second reservoir comprises:
a second water inlet pipe and a second water outlet pipe arranged on a bottom of the second reservoir.

16. The data center according to claim 10, wherein the compressor is a magnetic levitation centrifugal compressor.

17. The data center according to claim 10, wherein the refrigerant drive apparatus is a fluorine pump.

18. The data center according to claim 10, wherein the throttling apparatus is an electronic expansion valve, a thermal expansion valve, or a capillary tube.
